(19) United States
(12) Patent Application Publication
(10) Pub. No.: US 2010/0085700 A1
(43) Pub. Date: Apr. 8, 2010

(54) External hard disk case box

(75) Inventor: Fu-Guo Chang, HsinTien City (TW)

Correspondence Address: ROGER H. CHU, 19499 ERIC DRIVE, SARATOGA, CA, 95070, US

(73) Assignee: SSI COMPUTER CORP., HsinTien City (TW)

(21) Appl. No.: 12/247,224

(22) Filed: Oct. 8, 2008

(51) Int. Cl. H05K 5/00

(52) U.S. Cl. 361/679.33

(57) ABSTRACT

The present invention discloses an external hard disk case box including a casing, a circuit board, a power socket, at least one terminal, a position restoring device and a fan. The fan is installed on the casing and proximate to a corresponding insert slot of the casing, such that when the external hard disk case box is used for an application, the hard disk is inserted into the insert slot of the casing, and the heat produced by the hard disk can be dissipated immediately and quickly by the fan, so as to enhance the heat dissipating efficiency.

### FIELD OF THE INVENTION

The present invention relates to an external hard disk case box, and more particularly to an external hard disk case box that improves the heat dissipating efficiency.

### BACKGROUND OF THE INVENTION

In our living environment, a family usually has a personal computer for work, learning, entertainment or other purposes, and the personal computer usually comes with a main system and input and output devices, and the output devices generally include a screen, a printer and a speaker, and the input devices generally include a keyboard and a mouse, and the main system generally includes a motherboard, a central processing unit, a power supply, a memory, and a hard disk for storing data, and an optical disk drive, and the motherboard usually comes with a plurality of ports for connecting the aforementioned input and output devices.

From the description above, a traditional hard disk is installed directly in an external connecting box, and a general user usually prepares several hard disks for storing data or backing up data, such that if the user needs to change a hard disk for an application, the user must remove the housing of the main system first, and then remove the screws by a screwdriver for changing the hard disk, and finally reverse the foregoing procedure to reinstall the screws and housing. Obviously, such arrangement incurs a complicated procedure and causes tremendous inconvenience to users for changing a hard disk.

To overcome the foregoing issue, a so-called external hard disk case box is introduced to the market, and the external hard disk case box is provided for externally connecting a hard disk, so as to solve the installation problems of the conventional hard disk.

However, the external hard disk case boxes available in the market do not have a good heat dissipating design, and the large quantity of heat produced during the operation of the hard disk is still a big issue that requires feasible solutions and further improvements.

### SUMMARY OF THE INVENTION

It is a primary objective of the present invention to overcome the shortcomings of the prior art by providing an external hard disk case box in accordance with the present invention.

To achieve the foregoing objective, the present invention provides an external hard disk case box comprising a casing, a circuit board, a power socket, at least one terminal, a position restoring device and a fan, wherein the casing includes an insert slot, and the circuit board is installed in the casing, and the circuit board includes a port corresponding to an insert slot of the casing.

The power socket is installed to and exposed from the casing, and the power socket is electrically coupled to the circuit board, and at least one terminal is installed to and exposed from the casing and electrically coupled to circuit board.

The position restoring device is installed to the casing, and the position restoring device includes a press button and a restoring spring, wherein the press button is exposed from the casing and slidably moved with respect to the casing, and the restoring spring is abutted between the press button and the casing for providing a position restoring force to the press button.

The fan is installed at the casing and corresponding to a proximate insert slot.

When the external hard disk case box of the invention is inserted into the insert slot of the casing for the application of a hard disk, the heat produced during the operation of the hard disk can be dissipated immediately and quickly to enhance the heat dissipating efficiency.

### BRIEF DESCRIPTION OF THE DRAWINGS

FIG. 1 is a perspective view of a first preferred embodiment of the invention;

FIG. 2 is a front view of a first preferred embodiment of the invention;

FIG. 3 is a rear view of a first preferred embodiment of the invention;

FIG. 4 is a perspective view of a second preferred embodiment of the invention;

FIGS. 5A to 5C show the operating procedure of a lever structure of a fan at the rear of a casing in accordance with the invention; and

FIGS. 6A to 6C show the operating procedure of a lever structure of a fan at the bottom of a casing in accordance with the invention.

### DETAILED DESCRIPTION

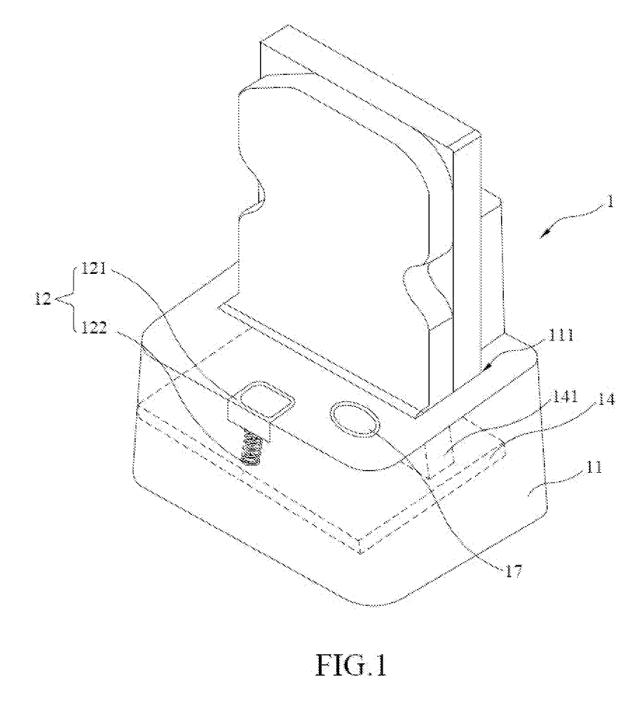

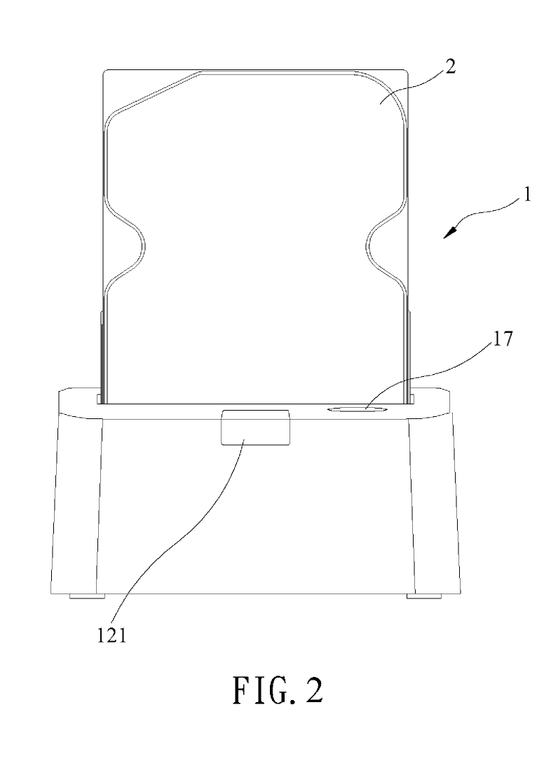

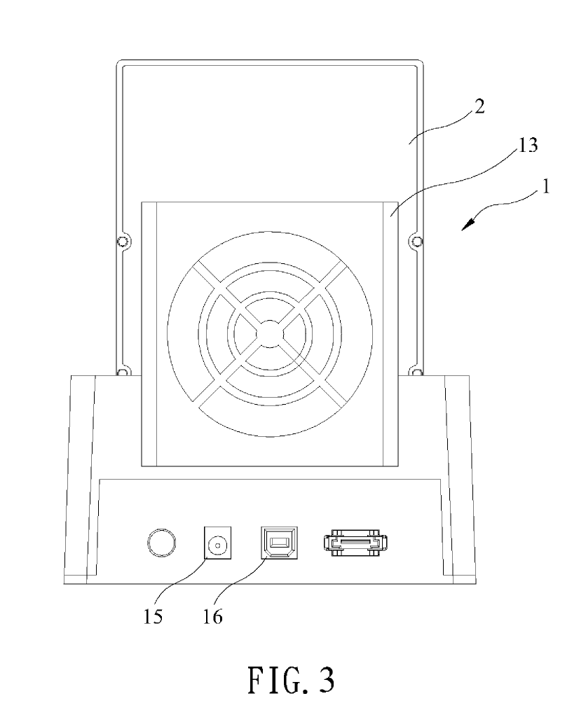

With reference to FIGS. 1 to 3 for a perspective view, a front view and a rear view of an external hard disk case box in accordance with a first preferred embodiment of the present invention respectively, the external hard disk case box 1 comprises a casing 11, a circuit board 14, a power socket 15, a terminal 16, a position restoring device 12 and a fan 13.

The casing 11 includes a large slot 111, and the circuit board 14 is installed in the casing 11. The circuit board 14 includes a port 141 corresponding to the large slot 111 of the casing 11.

When use, a hard disk 2 is inserted into the large slot 111 of casing 11, and a connector (not shown in the figure) of the hard disk 2 is inserted into the corresponding port 141 of the circuit board 14 for an application of the hard disk 2, such as a data access of the hard disk 2.

The power socket 15 is installed to and exposed from the casing 11, and the power socket 15 is electrically coupled to the circuit board 14. The terminal 16 is installed to and exposed from the casing 11, and the terminal 16 is electrically coupled to the circuit board 14. In this embodiment, the terminal 16 is a universal serial bus (USB) terminal, and the terminal 16 is one selected from the collection of a USB interface, a FireWire interface, an e-SATA interface, a 1394A interface, a 1394B interface, an optical fiber interface, a LAN and a combination of the above.

The position restoring device 12 is installed at the casing 11, and the position restoring device 12 includes a press button 121 and a restoring spring 122, wherein the press button 121 is exposed from the casing 11 and slidably moved with respect to the casing 11, and the restoring spring 122 is abutted between the press button 121 and the casing 11 for providing a position restoring force to the press button 121.

The fan 13 is installed on the casing 11 and corresponding to a proximate large slot 111 of the casing 11.

This preferred embodiment further comprises an indicating lamp 17 installed to and exposed from the casing 11, and the indicating lamp 17 is electrically coupled to the circuit board 14.

With the foregoing elements, the hard disk 2 can be inserted into the casing 11 through the large slot 111 of the casing 11 for the application of the hard disk 2, and the indicating lamp 17 is provided for indicating the current using status. If the hard disk is not in use, the press button 121 of the position restoring device 12 can be pushed to pop the hard disk 2 up (by a lever mechanism described as follows) and remove the hard disk 2, and the restoring spring 122 provides a position restoring force to the press button 121 to resume the press button 121 to its original position after pressing.

Since the fan 13 is installed corresponding to the large slot 111 of the casing 11, and the fan 13 is installed corresponding to the proximate hard disk 2, therefore the heat produced by the operation of the hard disk 2 can be dissipated immediately and quickly by the fan 13 to improve the heat dissipating efficiency.

It is noteworthy to point out that the way of installing the fan 13 is not limited to the foregoing embodiment only, but the fan 13 can be mounted onto the casing 11 by screws, or latched directly onto the casing 11, or even installed directly onto the casing 11. Of course, any other method with an equivalent effect can be used, such as installing the fan 13 at the bottom or any other position of the casing 11.

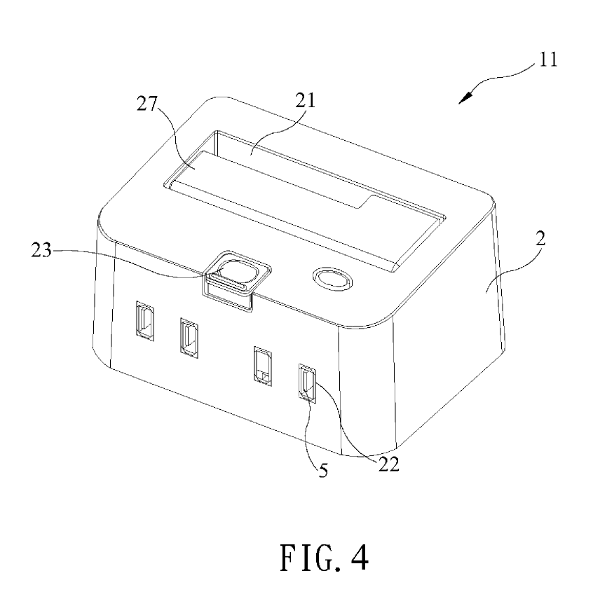

With reference to FIG. 4 for a perspective view of a second preferred embodiment of the present invention, the external hard disk case box 1 further comprises a panel 27 installed at an upper half of the casing 11 while maintaining a small slot 21 to be exposed from the casing 11, such that the panel 27 is not closely attached onto the casing 11. If an external hard disk 2 is larger than the hole diameter of the small slot 21, the hard disk 2 is pressed downward and stored into the casing 11, and the design of the insert slot is in compliance with the specification of a 2.5-inch external hard disk.

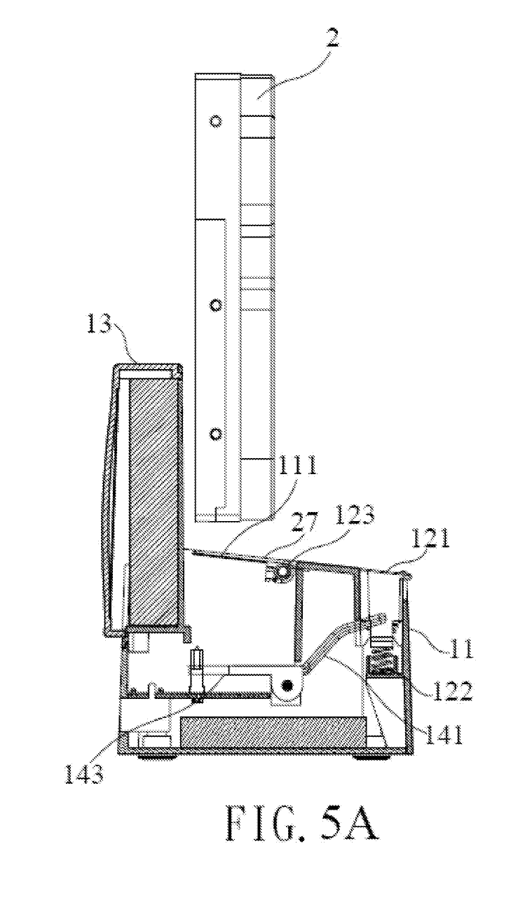

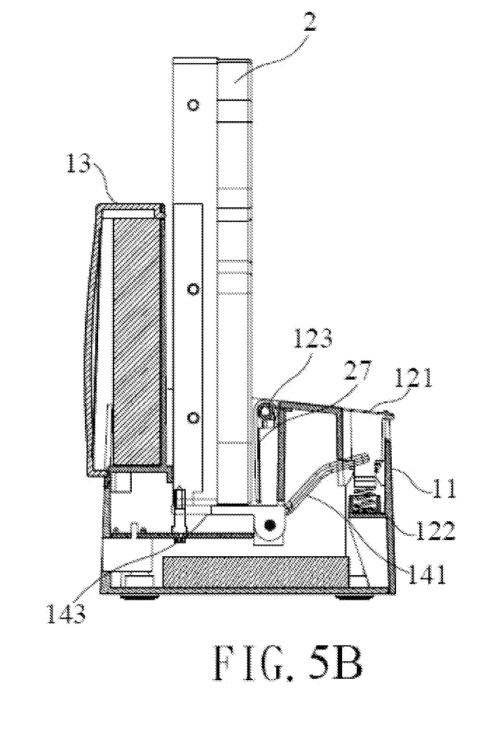

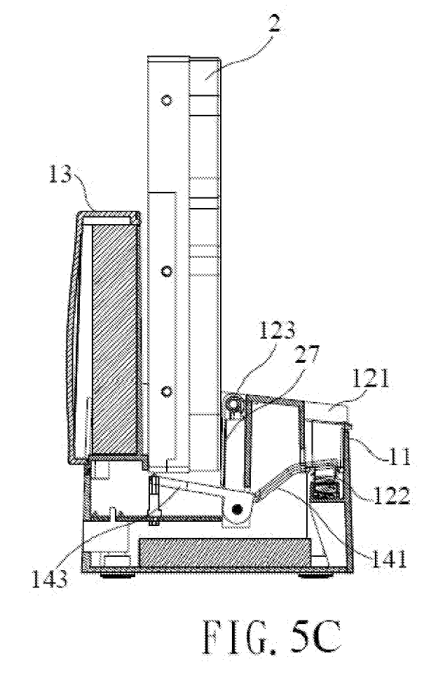

With reference to FIGS. 5A to 5C for the operating steps of a lever structure of a fan at the rear of a casing in accordance with the invention, the hard disk 2 is being inserted from top to bottom into the casing 11 as shown in FIG. 5A. Now, the panel 27 is maintained at the entrance of the large slot 111 by the torque of a button-head spring 123. The press button 121 is abutted to resume its original position by the spring 122. Both pushing-up board 143 and pressing-down board 141 of the lever mechanism 14 remain at their original positions. In FIG. 5B, the hard disk 2 has been inserted and mounted into the casing 11, and now the panel 27 is pressed into the large slot 111, and the button-head spring 123 is situated at a force applying condition. The pushing-up board 143 and the pressing-down board 141 also remain their original positions. In FIG. 5C, a downward force F is applied to the press button 121 to move the press button 121 downward and drive the pressing-down board 141 and compress the spring 122. Due to the principle of lever, the pushing-up board 143 is pushed upward to move the hard disk 2 upward accordingly. After the hard disk 2 is separated from the casing 11, the panel 27 is resumed to its original position by the torque of the button-head spring 123. The press button 121 is moved upward to resume its original position by the resilience of the spring 122.

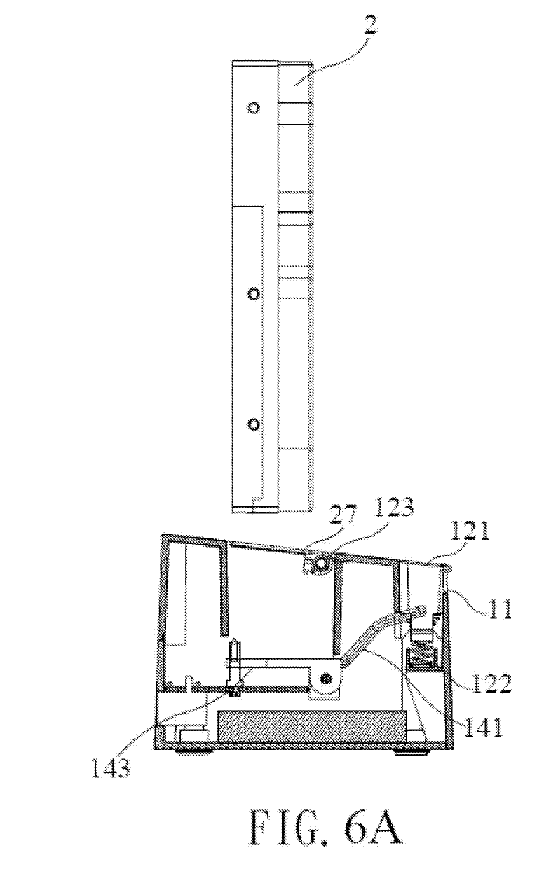

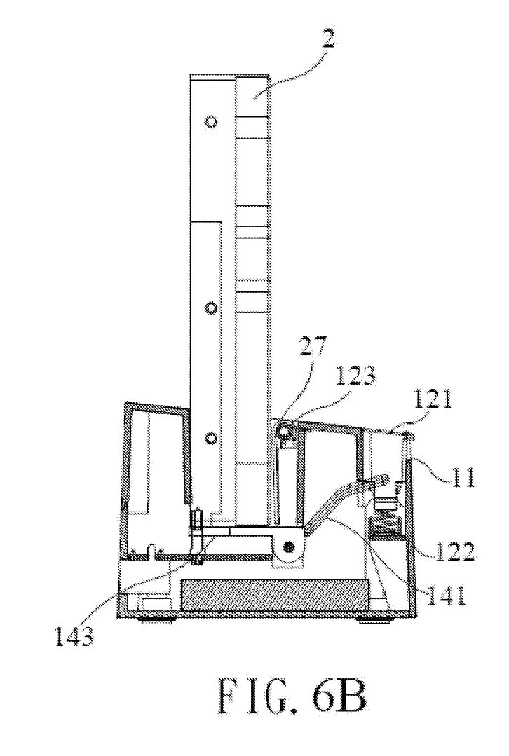

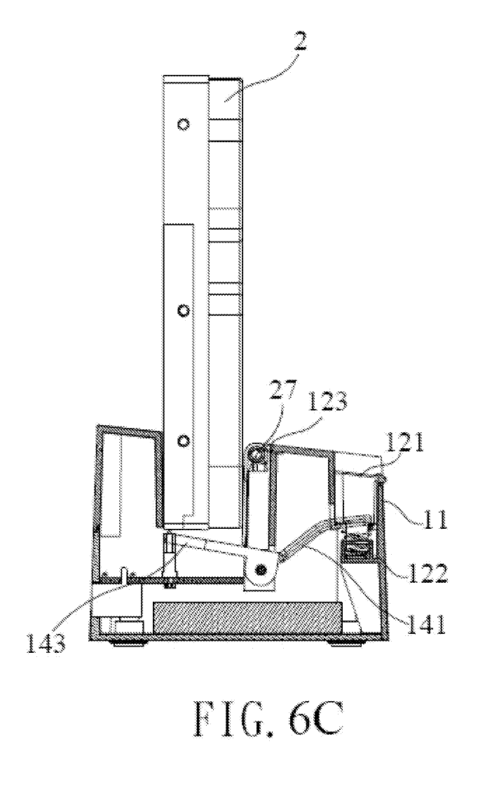

With reference to FIGS. 6A to 6C for the operating steps of a lever structure of a fan at the bottom of a casing in accordance with the invention, the hard disk 2 is being inserted from top to bottom into the casing 11 as shown in FIG. 6A. Now, the panel 27 remains at the entrance of the large slot 111 due to the torque of the button-head spring 123. The press button 121 is pressed against its original position by the spring 122. Both pushing-up board 143 and pressing-down board of the lever mechanism 14 remain their positions. In FIG. 6B, the hard disk 2 has been inserted and mounted into the casing 11. Now, the panel 27 is pressed into the large slot 111, and the button-head spring 123 is situated at a force applying condition. Both pushing-up board 143 and pressing-down board 141 remain at their original positions. In FIG. 6C, a downward force F is applied to the press button 121 to move the press button 121 downward and drive the pressing-down board 141 to compress the spring 122. Therefore, the pushing-up board 143 is pushed upward by the principle of lever to move the hard disk 2 upward accordingly. After the hard disk 2 is separated from the casing 11, the panel 27 is resumed to its original position by the torque of the button-head spring 123. The press button 121 is moved upward to resume its original position by the resilience of the spring 122. In the figures, the fan 13 is installed at the bottom or under the casing 11 for its operation.

While the invention has been described by means of specific embodiments, numerous modifications and variations could be made thereto by those skilled in the art without departing from the scope and spirit of the invention set forth in the claims.

What is claimed is:

1. An external hard disk case box, comprising:
a casing, including an insert slot;
a circuit board, installed in the casing, and including a port corresponding to the insert slot;
a power socket, installed to and exposed from the casing, and electrically coupled to the circuit board;
at least one terminal, installed to and exposed from the casing, and electrically coupled to the circuit board;
a position restoring device, installed at the casing, and including a press button and a restoring spring, and the press button being exposed from the casing and slidably moved with respect to the casing, and the restoring spring being pressed between the press button and the casing for providing a position restoring force to the press button; and
a fan, installed at the rear of the casing and proximate to the corresponding insert slot.

2. The external hard disk case box, wherein of claim 1, further comprising an indicating lamp, installed to and exposed from the casing, and electrically coupled to the circuit board.

3. The external hard disk case box, wherein of claim 1, wherein at least one terminal is a universal serial bus (USB) terminal.

4. The external hard disk case box, wherein of claim 1, further comprising a panel installed to an upper half of the casing while maintaining an insert slot to be exposed from the casing, and the panel being not closely attached to the casing, such that if an external hard disk is larger than the hole diameter of the insert slot, the external hard disk will be pressed downward and stored into the casing.

5. The external hard disk case box, wherein of claim 1, wherein the insert slot is in compliance with the specification of a 2.5-inch external hard disk.

6. The external hard disk case box, wherein of claim 1, wherein at least one terminal is selected from the collection of a USB interface, a FireWire interface, an e-SATA interface, a 1394A interface, a 1394B interface, an optical fiber interface, a LAN and a combination of the above.

7. An external hard disk case box, comprising:
a casing, including an insert slot;
a circuit board, installed in the casing, and including a port corresponding to the insert slot;
a power socket, installed to and exposed from the casing, and electrically coupled to the circuit board;
at least one terminal, installed to and exposed from the casing, and electrically coupled to the circuit board;
a position restoring device, installed at the casing, and including a press button and a restoring spring, and the press button being exposed from the casing and slidably moved with respect to the casing, and the restoring spring being pressed between the press button and the casing for providing a position restoring force to the press button; and
a fan, installed at the bottom of the casing.

8. The external hard disk case box of claim 7, further comprising an indicating lamp installed to and exposed from the casing, and electrically coupled to the circuit board.

9. The external hard disk case box of claim 7, wherein at least one terminal is a universal serial bus (USB) terminal.

10. The external hard disk case box of claim 7, further comprising a panel installed at an upper half of the casing while maintaining an insert slot to be exposed from the casing, and the panel being not closely attached to the casing, such that if an external hard disk is larger than the hole diameter of the insert slot, the external hard disk will be pressed downward and stored into the casing.

11. The external hard disk case box of claim 7, wherein the insert slot is in compliance with the specification of a 2.5-inch external hard disk.

12. The external hard disk case box of claim 7, wherein at least one terminal is selected from the collection of a USB interface, a FireWire interface, an e-SATA interface, a 1394A interface, a 1394B interface, an optical fiber interface, a LAN and a combination of the above.
